(19) United States
(12) Patent Application Publication
(10) Pub. No.: US 2023/0333462 A1
(43) Pub. Date: Oct. 19, 2023

(54) PELLICLE MEMBRANE FOR A LITHOGRAPHIC APPARATUS

(71) Applicant: ASML NETHERLANDS B. V., Veldhoven (NL)

(72) Inventors: Ties Wouter VAN DER WOORD, Eindhoven (NL); Alexander Ludwig KLEIN, Eindhoven (NL); Zomer Silvester HOUWELING, Eindhoven (NL); Inci DONMEZ NOYAN, Eindhoven (NL); Volker Dirk HILDENBRAND, Eindhoven (NL); Adrianus Johannes Maria HILDENBRAND, Eindhoven (NL); Johan Hendrik GIESBERS, Vlijmen (NL)

(73) Assignee: ASML NETHERLANDS B. V., Veldhoven (NL)

(21) Appl. No.: 18/022,508

(22) PCT Filed: Aug. 5, 2021
(86) PCT No.: PCT/EP2021/071832

§ 371 Date: Feb. 21, 2023

(30) Foreign Application Priority Data
Sep. 3, 2020 (EP) 20194445.1

(51) Int. Cl. G03F 1/62; G03F 1/80

(52) U.S. Cl. CPC G03F 1/62; G03F 1/80

(57) ABSTRACT

A pellicle membrane for use in a lithographic apparatus, the pellicle membrane characterized by in plane variation in composition is described. A method of manufacturing a pellicle membrane, the method including: providing a first material layer on a sacrificial layer on a substrate; providing a photoresist layer on the first material layer; patterning the photoresist layer; etching the first material layer to form a patterned surface; and either i) depositing a layer of a second material on the patterned surface and subsequently lifting off the portion of the second material deposited on the patterned photoresist layer, or ii) removing the remaining photoresist layer, depositing a layer of a second material on the patterned surface, and subsequently planarizing the surface.

### CROSS-REFERENCE TO RELATED APPLICATIONS

This application claims priority of EP application 20194445.1 which was filed on Sep. 3, 2020 and which is incorporated herein in its entirety by reference.

The present invention relates to pellicle membrane for a lithographic apparatus, a pellicle assembly for a lithographic apparatus, and a use of a pellicle membrane in a lithographic apparatus or method. The present invention also relates to methods of manufacturing pellicle membranes, as well lithographic apparatuses comprising pellicle membranes of the present invention.

### BACKGROUND

A lithographic apparatus is a machine constructed to apply a desired pattern onto a substrate. A lithographic apparatus can be used, for example, in the manufacture of integrated circuits (ICs). A lithographic apparatus may for example project a pattern from a patterning device (e.g. a mask) onto a layer of radiation-sensitive material (resist) provided on a substrate.

The wavelength of radiation used by a lithographic apparatus to project a pattern onto a substrate determines the minimum size of features which can be formed on that substrate. A lithographic apparatus which uses EUV radiation, being electromagnetic radiation having a wavelength within the range 4-20 nm, may be used to form smaller features on a substrate than a conventional lithographic apparatus (which may for example use electromagnetic radiation with a wavelength of 193 nm).

A lithographic apparatus includes a patterning device (e.g. a mask or reticle). Radiation is provided through or reflected off the patterning device to form an image on a substrate. A membrane assembly, also referred to as a pellicle, may be provided to protect the patterning device from airborne particles and other forms of contamination. Contamination on the surface of the patterning device can cause manufacturing defects on the substrate.

Pellicles may also be provided for protecting optical components other than patterning devices. Pellicles may also be used to provide a passage for lithographic radiation between regions of the lithography apparatus which are sealed from one another. Pellicles may also be used as filters, such as spectral purity filters or as part of a dynamic gas lock of a lithographic apparatus.

A mask assembly may include the pellicle which protects a patterning device (e.g. a mask) from particle contamination. The pellicle may be supported by a pellicle frame, forming a pellicle assembly. The pellicle may be attached to the frame, for example, by gluing or otherwise attaching a pellicle border region to the frame. The frame may be permanently or releasably attached to a patterning device.

Due to the presence of the pellicle in the optical path of the EUV radiation beam, it is necessary for the pellicle to have high EUV transmissivity. A high EUV transmissivity allows a greater proportion of the incident radiation through the pellicle. In addition, reducing the amount of EUV radiation absorbed by the pellicle may decrease the operating temperature of the pellicle. Since transmissivity is at least partially dependent on the thickness of the pellicle, it is desirable to provide a pellicle which is as thin as possible whilst remaining reliably strong enough to withstand the sometimes hostile environment within a lithography apparatus.

It is therefore desirable to provide a pellicle which is able to withstand the harsh environment of a lithographic apparatus, in particular an EUV lithography apparatus. It is particularly desirable to provide a pellicle which is able to withstand higher powers than previously.

Whilst the present application generally refers to pellicles in the context of lithography apparatus, in particular EUV lithography apparatus, the invention is not limited to only pellicles and lithography apparatus and it is appreciated that the subject matter of the present invention may be used in any other suitable apparatus or circumstances.

For example, the methods of the present invention may equally be applied to spectral purity filters. Some EUV sources, such as those which generate EUV radiation using a plasma, do not only emit desired ‘in-band’ EUV radiation, but also undesirable (out-of-band) radiation. This out-of-band radiation is most notably in the deep UV (DUV) radiation range (100 to 400 nm). Moreover, in the case of some EUV sources, for example laser produced plasma EUV sources, the radiation from the laser, usually at 10.6 microns, presents a significant out-of-band radiation.

In a lithographic apparatus, spectral purity is desired for several reasons. One reason is that the resist is sensitive to out of-band wavelengths of radiation, and thus the image quality of patterns applied to the resist may be deteriorated if the resist is exposed to such out-of-band radiation. Furthermore, out-of-band radiation, for example the 10.6 micron radiation in some laser produced plasma sources, leads to unwanted and unnecessary heating of the patterning device, substrate, and optics within the lithographic apparatus. Such heating may lead to damage of these elements, degradation in their lifetime, and/or defects or distortions in patterns projected onto and applied to a resist-coated substrate.

The present invention has been devised in an attempt to address at least some of the problems identified above.

### SUMMARY OF THE INVENTION

According to a first aspect of the present invention, there is provided a pellicle membrane for use in a lithographic apparatus, said pellicle membrane characterised by in-plane variation in composition.

Existing pellicle membranes may include a number of stacked layers in order to provide the desired optical and physical properties to allow them to be used in lithographic apparatus. As such, existing pellicle membranes vary in composition across their thickness, namely in a direction perpendicular to the plane of the pellicle membrane. Even in pellicle membranes which do not comprise a multi-layer stack, such as pellicle membranes comprising emissive crystals disposed within an amorphous matrix, the composition is intended to be the same across the plane of the pellicle membrane. In contrast, the pellicle membrane according to the present invention varies in composition in the plane of the pellicle membrane. In this way, it is possible to enhance the performance of the pellicle membrane.

The pellicle membrane may comprise two or more different materials. Although the pellicle membrane varies in composition in-plane, the pellicle membrane is preferably formed of distinct sections of materials which are in themselves uniform or substantially uniform in-plane. By having two or more different materials, the optical and physical properties of the pellicle membrane can be adjusted and optimised for the conditions within a lithographic apparatus. In particular, the emissivity and transmissivity of the overall pellicle membrane can be adjusted by altering the ratio of the two different materials as well as the materials themselves. For example, in order to increase transmissivity, a greater proportion of a more transmissive material may be used. Similarly, where it is desired to have a more emissive pellicle membrane, a greater proportion of a relatively more emissive material may be used. The shapes of the distinct sections of material may or may not be repetitive or uniformly distributed, depending on which function is predominantly desired in the film. For example, a greater proportion of relatively less transmissive material may be provided at the edges of the film and a greater proportion of relatively more emissive material. At or towards the center of the film, there may be provide a greater proportion of the relatively more EUV transmissive material and a lower proportion of the relatively less transmissive material. The film inhomogeneity is on the longitudinal side (or the longer dimension, or in plane) instead of being transverse/perpendicular to the film, which is how it would be for layers forming the pellicle film as known in prior art. The first material is embedded in the second material in any suitable shapes chosen to maximize specific imaging requirements.

In one embodiment, one of the materials may form a web of interconnected portions in which a second material is embedded as discontinuous patches. The interconnected material may for simplicity of terminology be defined as a grid. However, the grid is different from prior art pellicle grids aimed to provide mechanical support. As such, the grid is embedded in the pellicle membrane itself as opposed to being affixed to a face of the membrane. In other words, the grid is an integral part of the pellicle membrane, as opposed to existing pellicle membranes which may include a non-integral grid for support. At least one of the materials may be arranged as a grid. A grid may be any shape of an interconnected first material in which a second material is embedded in plane to form a pellicle film. Where one of the materials forms a repetitive pattern in the film, the other material of the film will have a shape distribution which may be defined as a regular grid shape. Preferably, the material comprising the grid has a higher emissivity than the other material of the pellicle membrane. As such, the grid comprises a web of interconnected portions. Since the material comprising the grid is selected to have high emissivity, the entirety of the pellicle membrane retains it emissive properties due to the interconnected configuration. This is advantageous as a higher emissivity can reduce the operating temperature of the pellicle membrane, which thereby serves to prolong the lifetime of the pellicle membrane. Of course, it will be appreciated that the material comprising the grid may have a lower emissivity than the other material of the pellicle membrane in some embodiments. In this way, the interconnected material may have relatively higher transmissivity than the material forming the discontinuous patches. It will also be appreciated that in other embodiments, the two materials may form alternating shapes without having interconnected portions. As such, the two materials may be configured in a chess or checkers board configuration. The key feature of the present invention is the presence of two materials combined in a single plane having a smooth surface in order to ensure appropriate imaging, while combining two functions, namely thermal control and EUV transmission. One of the materials may have an EUV transmissivity of greater than or equal to 75%, greater than or equal to 80%, greater than or equal to 85%, greater than or equal to 90%, or greater than or equal to 95%. One of the materials may have an emissivity in the range of from 0.01 to 0.15, preferably from 0.015 to 0.1, or preferably from 0.02 to 0.09.

The grid includes areas in which a different material may be received. As such, the composition of the pellicle membrane varies in the plane of the grid. It is to be understood that the grid forms part of the pellicle membrane itself rather than merely acting as a support feature, as in the case of grid-supported pellicles. In a grid-supported pellicle, the pellicle membrane itself does not vary in-plane, but is uniform. As such the pellicle membrane according to any aspect of the present invention may be a free-standing pellicle membrane. In cases where a grid is provided on top of or below a closed film, there will be a greater absorbance of EUV light in the areas where there is overlap between the film and the grid. Since the variation in the present pellicle membrane is in-plane and the grid is incorporated into the closed film itself, there is a net gain in EUV transmissivity compared to previous pellicle membranes. In addition, the pellicle membrane according to the present invention have slower degradation. Without wishing to be bound by scientific theory, it is believed that where a grid is positioned on top of a closed membrane, there is a significantly larger surface area compared to when the grid is incorporated into the film itself. Degradation of silicon, for example, mainly comprises oxidation at the surface. As such, having a lower surface area leads to lower degradation in terms of EUV transmissivity.

The grid may be of any shape. The grid may include a regular pattern of repeating sub-units. The grid may be a triangular grid, a rectangular grid, a square grid, or a hexagonal grid. For example, where the grid is a triangular grid, the material comprising the grid may form an array of triangles. Indeed the grid may comprise any repeating regular shape, such as, for example, circles. The grid may be regular or irregular. A regular grid is one which has a repeating pattern of regular shapes. An irregular grid is a grid which has a repeating pattern of irregular shapes.

The material comprising the grid may comprise one or more of: zirconium, molybdenum ruthenium, tungsten, zirconium silicide, molybdenum silicide, ruthenium silicide, tungsten silicide, zirconium silicon nitride, molybdenum silicon nitride, ruthenium silicon nitride, and tungsten silicon nitride. These metals and compounds have high emissivity and are therefore well suited as a material for the grid. Indeed any emissive material may be used. Molybdenum silicide is preferred.

At least one of the materials may be arranged as a series of distinct regions. These distinct regions may be in the form of patches. The distinct regions may be bordered by the grid. The distinct regions may be circumferentially surrounded by the grid. For example, where the grid is a square grid, the series of distinct regions may be in the form of an array of squares bordered by the material of the grid. The series of distinct regions may be regularly shaped and/or spaced. The series of distinct regions may have different spacing and/or shapes. The material comprising the series of distinct regions may have a higher EUV-transmissivity than the other material of the pellicle membrane. Of course, the reverse configuration is also contemplated. In other embodiments, one of the materials comprising the grid or the distinct regions may have a higher EUV transmissivity and emissivity than the other material. The material comprising the distinct regions may comprise silicon. The material comprising the distinct regions may comprise silicon nitride and/or silicon carbide. The silicon may be in any form. The silicon may comprise one of more of p-Si, a-Si, nc-Si, mono-Si, or combinations thereof.

By having a series of areas of the pellicle membrane which are relatively more transmissive to EUV radiation, the overall pellicle membrane may have high transmissivity, whilst also retaining high emissivity as a result of the grid comprises relatively more emissive material. Silicon is preferred due to its high EUV transmissivity and ability to withstand the environment of an operating lithography apparatus.

The grid may be configured to filter out undesired wavelengths of incident electromagnetic radiation. This may be achieved by varying the pitch and/or the ratio of materials in the pellicle membrane. This may also be achieved by adjusting the thickness of the gridlines.

The pellicle membrane may include a blazed grid. In particular, a surface of the grid may be angled to adjust the reflectivity of different wavelengths of incident light. As such, the grid can be configured to reflect undesired wavelengths of incident light to reduce the amount of light having undesired wavelengths from passing through the pellicle membrane. As such, the pellicle membrane may act as a spectral purity filter.

The pellicle membrane may be a closed-film membrane. An advantage of using a closed-film is that there are no gaps or spaces in the membrane through which contaminants may pass.

At least a portion of the pellicle membrane may comprise a stack of material layers. Existing pellicle membranes can include stacked material layers which are selected to provide the desired optical and physical properties. In embodiments of the present invention, the pellicle membrane may include such stacks of material layers as the first and/or second material. For example, the pellicle membrane may comprise distinct regions of membrane comprising stacked layers or the grid may comprise stacked layers. The stacked layers may include a core layer with one or more additional layers. The additional layers may include one or more of emissive layers as described herein, such as molybdenum, ruthenium, zirconium, tungsten, and silicides or silicon nitrides thereof. The additional layers may include protective layers configured to protect the underlying emissive layer.

According to a second aspect of the present invention, there is provided a method of manufacturing a pellicle membrane, said method including providing a sacrificial layer on a substrate The method includes providing a first material layer on the sacrificial layer and providing a photoresist layer on the first material layer. The photoresist layer is patterned and the first material layer is etched to form a patterned surface. The method further comprises either i) depositing a layer of a second material on the patterned surface and subsequently lifting off the portion of the second material deposited on the patterned photoresist layer, or ii) removing the remaining photoresist layer, depositing a layer of a second material on the patterned surface, and subsequently planarizing the surface.

The method according to the second aspect of the present invention provides a way of manufacturing the unique pellicle membrane according to the first aspect of the present invention. This method allows the formation of a grid structure in the patterning step and for the provision of a second material within the grooves or channels formed in the patterning step.

One or both of the first material layer and the second material layer may be deposited by physical or chemical deposition.

The substrate may comprise silicon. Any morphology of silicon may be used.

The surface may be planarized by one or both of chemical-mechanical planarization and etching. It is desirable for the surface of the pellicle membrane to be flat such that it has consistent optical properties.

The surface of the pellicle may be polished. Polishing may be effected (put into effect) by ion polishing.

The second material may be selectively grown via the deposition of an incubation or precursor layer prior to growth. The second material may be selectively grown within the etched pattern on the patterned surface. By selectively growing the second material, the amount of further processing, such as chemical-mechanical planarization, etching or polishing is reduced.

One of the first and second materials may be silicon, silicon nitride, silicon carbide, or combinations thereof. The other of the first and second materials may be selected from zirconium, molybdenum, ruthenium, tungsten, zirconium silicide, molybdenum silicide, ruthenium silicide, tungsten silicide, zirconium silicon nitride, molybdenum silicon nitride, ruthenium silicon nitride, and tungsten silicon nitride.

According to a third aspect of the present invention, there is provided a pellicle assembly for use in a lithographic apparatus, said pellicle assembly including the pellicle membrane according to the first aspect of the present invention.

According to a fourth aspect of the present invention, there is provided the use of a pellicle membrane or pellicle assembly according to any aspect of the present invention in a lithographic apparatus or method.

According to a fifth aspect of the present invention, there is provided a lithographic apparatus comprising a pellicle membrane or pellicle assembly according to any aspect of the present invention.

It will be appreciated that features described in respect of one embodiment may be combined with any features described in respect of another embodiment and all such combinations are expressly considered and disclosed herein.

### BRIEF DESCRIPTION OF THE DRAWINGS

Embodiments of the invention will now be described, by way of example only, with reference to the accompanying schematic drawing in which corresponding reference symbols indicate corresponding parts, and in which:

FIG. 1 depicts a lithographic apparatus according to an embodiment of the invention;

FIG. 2 is a schematic depiction of a pellicle membrane according to an embodiment of the present invention; and

FIG. 3 is a flowsheet of a method of manufacturing a pellicle membrane according to an embodiment of the present invention.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION

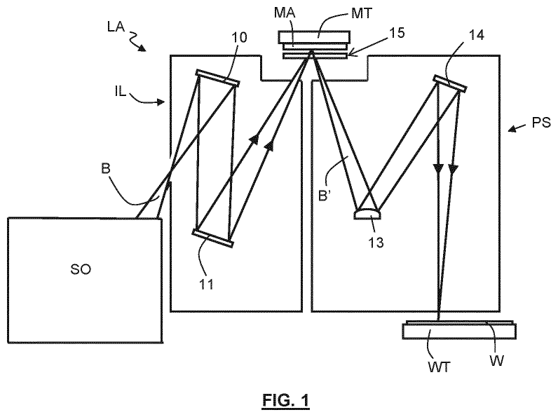

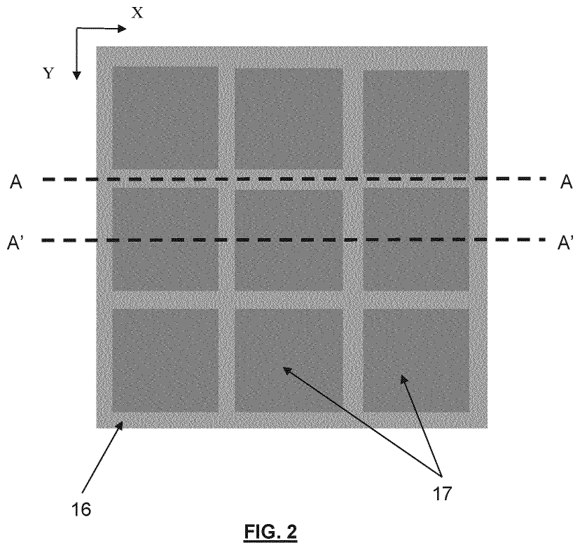

FIG. 1 shows a lithographic system including a pellicle 15 (also referred to as a membrane assembly) according to the present invention. The lithographic system comprises a radiation source SO and a lithographic apparatus LA. The radiation source SO is configured to generate an extreme ultraviolet (EUV) radiation beam B. The lithographic apparatus LA comprises an illumination system IL, a support structure MT configured to support a patterning device MA (e.g. a mask), a projection system PS and a substrate table WT configured to support a substrate W. The illumination system IL is configured to condition the radiation beam B before it is incident upon the patterning device MA. The projection system is configured to project the radiation beam B (now patterned by the mask MA) onto the substrate W. The substrate W may include previously formed patterns. Where this is the case, the lithographic apparatus aligns the patterned radiation beam B with a pattern previously formed on the substrate W. In this embodiment, the pellicle 15 is depicted in the path of the radiation and protecting the patterning device MA. It will be appreciated that the pellicle 15 may be located in any required position and may be used to protect any of the mirrors in the lithographic apparatus.

The radiation source SO, illumination system IL, and projection system PS may all be constructed and arranged such that they can be isolated from the external environment. A gas at a pressure below atmospheric pressure (e.g. hydrogen) may be provided in the radiation source SO. A vacuum may be provided in illumination system IL and/or the projection system PS. A small amount of gas (e.g. hydrogen) at a pressure well below atmospheric pressure may be provided in the illumination system IL and/or the projection system PS.

The radiation source SO shown in FIG. 1 is of a type which may be referred to as a laser produced plasma (LPP) source. A laser, which may for example be a CO₂ laser, is arranged to deposit energy via a laser beam into a fuel, such as tin (Sn) which is provided from a fuel emitter. Although tin is referred to in the following description, any suitable fuel may be used. The fuel may for example be in liquid form, and may for example be a metal or alloy. The fuel emitter may comprise a nozzle configured to direct tin, e.g. in the form of droplets, along a trajectory towards a plasma formation region. The laser beam is incident upon the tin at the plasma formation region. The deposition of laser energy into the tin creates a plasma at the plasma formation region. Radiation, including EUV radiation, is emitted from the plasma during de-excitation and recombination of ions of the plasma.

The EUV radiation is collected and focused by a near normal incidence radiation collector (sometimes referred to more generally as a normal incidence radiation collector). The collector may have a multilayer structure which is arranged to reflect EUV radiation (e.g. EUV radiation having a desired wavelength such as 13.5 nm). The collector may have an elliptical configuration, having two ellipse focal points. A first focal point may be at the plasma formation region, and a second focal point may be at an intermediate focus, as discussed below.

The laser may be separated from the radiation source SO. Where this is the case, the laser beam may be passed from the laser to the radiation source SO with the aid of a beam delivery system (not shown) comprising, for example, suitable directing mirrors and/or a beam expander, and/or other optics. The laser and the radiation source SO may together be considered to be a radiation system.

Radiation that is reflected by the collector forms a radiation beam B. The radiation beam B is focused at a point to form an image of the plasma formation region, which acts as a virtual radiation source for the illumination system IL. The point at which the radiation beam B is focused may be referred to as the intermediate focus. The radiation source SO is arranged such that the intermediate focus is located at or near to an opening in an enclosing structure of the radiation source.

The radiation beam B passes from the radiation source SO into the illumination system IL, which is configured to condition the radiation beam. The illumination system IL may include a facetted field mirror device 10 and a facetted pupil mirror device 11. The faceted field mirror device 10 and faceted pupil mirror device 11 together provide the radiation beam B with a desired cross-sectional shape and a desired angular distribution. The radiation beam B passes from the illumination system IL and is incident upon the patterning device MA held by the support structure MT. The patterning device MA reflects and patterns the radiation beam B. The illumination system IL may include other mirrors or devices in addition to or instead of the faceted field mirror device 10 and faceted pupil mirror device 11.

Following reflection from the patterning device MA the patterned radiation beam B enters the projection system PS. The projection system comprises a plurality of mirrors 13, 14 which are configured to project the radiation beam B onto a substrate W held by the substrate table WT. The projection system PS may apply a reduction factor to the radiation beam, forming an image with features that are smaller than corresponding features on the patterning device MA. A reduction factor of 4 may for example be applied. Although the projection system PS has two mirrors 13, 14 in FIG. 1, the projection system may include any number of mirrors (e.g. six mirrors).

The radiation sources SO shown in FIG. 1 may include components which are not illustrated. For example, a spectral filter may be provided in the radiation source. The spectral filter may be substantially transmissive for EUV radiation but substantially blocking for other wavelengths of radiation such as infrared radiation.

In an embodiment the membrane assembly 15 is a pellicle for the patterning device MA for EUV lithography. The membrane assembly 15 of the present invention can be used for a dynamic gas lock or for a pellicle or for another purpose. In an embodiment the membrane assembly 15 comprises a membrane formed from the at least one membrane layer configured to transmit at least 90% of incident EUV radiation. In order to ensure maximized EUV transmission and minimized impact on imaging performance it is preferred that the membrane is only supported at the border.

If the patterning device MA is left unprotected, the contamination can require the patterning device MA to be cleaned or discarded. Cleaning the patterning device MA interrupts valuable manufacturing time and discarding the patterning device MA is costly. Replacing the patterning device MA also interrupts valuable manufacturing time.

FIG. 2 depicts a plan view of a portion of a pellicle membrane 15 according to the present invention. The pellicle membrane 15 includes a grid 16 comprising a first material and a series of distinct regions of a second material 17 (only two of which are numbered). The length of the sides of the grid 16 may be around 300 nm. As such, it will be appreciated that the pellicle membrane may include a plurality of such portions depicted in FIG. 2. It will also be appreciated that this length is exemplary and is provided to indicate the order of magnitude of such a length. The invention is not particularly limited to this length, the length may be varied depending on the requirements of the pellicle membrane 15. The dotted lines A-A and A′-A′ are included to indicate how the pellicle membrane varies in composition in-plane. At position A-A, the line intersects only the material comprising the grid 16. As the line is moved to position A′-A′, the line intersects both the first material of the grid 16 as well as the second material 17. As such, the composition of the pellicle membrane varies in-plane. The grid is embedded within the pellicle membrane and forms parts of the pellicle membrane itself, as opposed to existing pellicle membranes which do not have an integral grid portion, even though they may have a supportive grid. In contrast, in existing pellicle membranes, there would be no difference in the materials which are intersected by the line A-A as it is moved across the surface of the pellicle membrane as existing pellicles have a uniform surface. The pellicle membrane of the present direction may preferably vary in the x and y direction (where the z-direction corresponds to the thickness of the pellicle membrane).

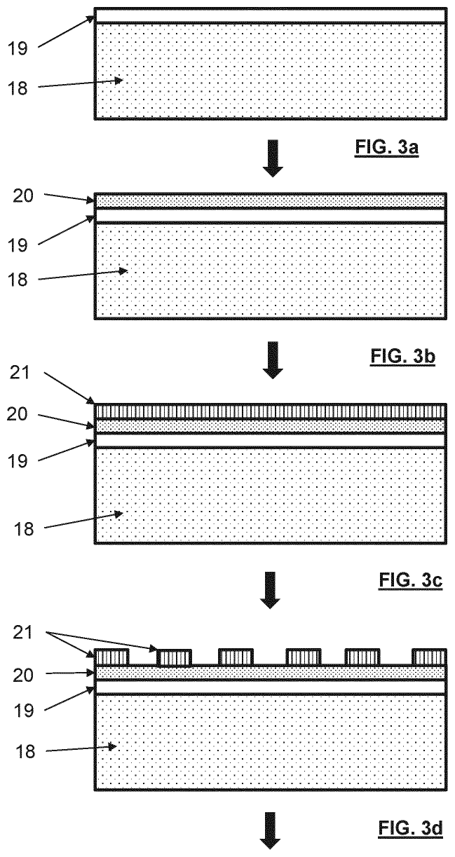

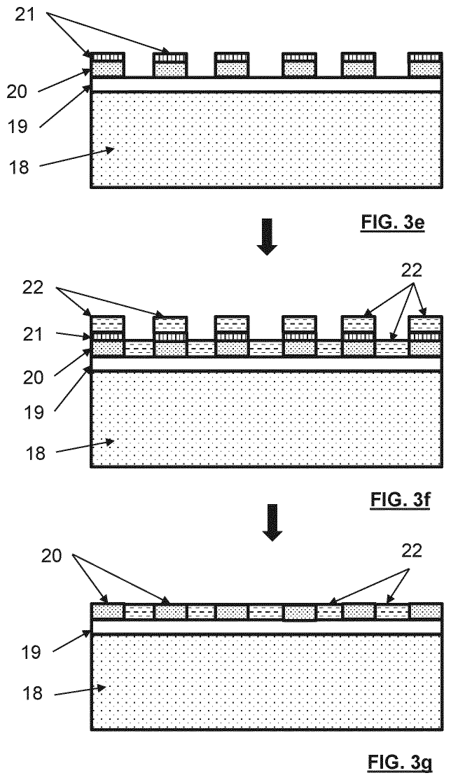

FIGS. 3a to 3g depict a method for manufacturing a pellicle membrane according to the present invention. The figures are schematic in nature and the relative dimensions of the various layers are not limiting on the invention. In a first step, a substrate 18 is provided and a sacrificial layer 19 is provided on the substrate 18. The substrate 18 preferably comprises silicon. In the next step, a first material layer 20 is provided on the sacrificial layer 19. Following this, a photoresist layer 21 is provided on the surface of the first material layer 20. The photoresist layer 21 is then patterned to define the layout of the grid of the final pellicle membrane. Once the photoresist layer 21 has been patterned, an etching step takes place which etches the underlying first material layer 20 to form a patterned surface. In an embodiment, the next step in the method is the deposition of a layer of a second material 22 on the patterned surface. As shown in FIG. 3f, the second material 22 is deposited within the channels formed by the earlier etching step as well as on top of the remaining areas including the photoresist layer 21. The remaining photoresist layer 21 and the overlying second material layer 22 may be lifted off to provide a pellicle membrane comprising the first material 20 and the second material 22. Subsequently, the top surface of the pellicle membrane may be planarized and/or polished to provide a planar surface. Polishing may be effected (put into effect) by ion polishing. In another embodiment, remaining portions of the photoresist layer 21 may be removed before the second material layer 22 is deposited. As such, the second material layer 22 may be provided on top of the first material layer 20 and would also be provided within the channels created by the patterning step. In order to provide a pellicle membrane with a planar surface, the excess second material 22 may be removed by planarizing. Planarizing may be effected (put into effect) by chemical-mechanical planarization, polishing, and/or etching. In another embodiment, the second material layer 22 may be selectively grown within the channels formed by the patterning step. This may be realised through the deposition of an incubation or precursor layer prior to growth. This incubation or precursor layer may be deposited either before or after the photoresist layer is removed following patterning. Again, planarizing may be carried out after the selective growth in order to provide a planar surface.

Further processing steps as are known in the art, such as back-side etching to etch away a portion of the substrate to leave a border to support the pellicle membrane, may be conducted in order to arrive at a final pellicle assembly.

While specific embodiments of the invention have been described above, it will be appreciated that the invention may be practiced otherwise than as described.

The descriptions above are intended to be illustrative, not limiting. Thus it will be apparent to one skilled in the art that modifications may be made to the invention as described without departing from the scope of the claims set out below.

1. A pellicle membrane for use in a lithographic apparatus, the pellicle membrane characterized by in-plane variation in composition.

2. The pellicle membrane according to claim 1, wherein the pellicle membrane comprises two or more different materials.

3. The pellicle membrane according to claim 2, wherein at least one of the materials is arranged as a grid.

4. The pellicle membrane according to claim 3, wherein the material comprising the grid has a higher emissivity than another material of the two or more different materials of the pellicle membrane.

5. The pellicle membrane according to claim 2, wherein at least one of the materials is arranged as a plurality of distinct regions.

6. The pellicle membrane according to claim 5, wherein the at least one material comprising the distinct regions has a higher EUV-transmissivity than another material of the two or more different materials of the pellicle membrane.

7. The pellicle membrane according to claim 3, wherein the grid is configured to filter out undesired wavelengths of incident electromagnetic radiation.

8. The pellicle membrane according to claim 1, comprising a blazed grid.

9. The pellicle membrane according to claim 1, wherein the pellicle membrane is a closed-film membrane.

10. (canceled)

11. The pellicle membrane according to claim 1, wherein at least a portion of the pellicle membrane comprises a stack of material layers.

12. The pellicle membrane according to claim 2, wherein one of the materials has an EUV transmissivity of greater than or equal to 75%.

13. The pellicle membrane according to claim 2, wherein one of the materials has an emissivity in the range of from 0.01 to 0.15.

14. A method of manufacturing a pellicle membrane, the method comprising:
providing a first material layer on a sacrificial layer on a substrate;
providing a photoresist layer on the first material layer;
patterning the photoresist layer;
etching the first material layer to form a patterned surface; and
either i) depositing a layer of a second material on the patterned surface and subsequently lifting off the portion of the second material deposited on the patterned photoresist layer, or ii) removing the remaining photoresist layer, depositing a layer of a second material on the patterned surface, and subsequently planarizing the surface.

15. (canceled)

16. The method according to claim 14, wherein the substrate comprises silicon.

17. (canceled)

18. The method according to claim 14, wherein a surface of the pellicle membrane is polished.

19. The method according to claim 14, wherein the second material is selectively grown via the deposition of an incubation or precursor layer prior to growth.

20. The method according to claim 14, wherein the first or second material is silicon, silicon nitride, silicon carbide or a combination selected therefrom.

21. The method according to claim 20, wherein the other of the first and second materials is zirconium, molybdenum, ruthenium, tungsten, zirconium silicide, molybdenum silicide, ruthenium silicide, tungsten silicide, zirconium silicon nitride, molybdenum silicon nitride, ruthenium silicon nitride, or tungsten silicon nitride.

22. A pellicle assembly for use in a lithographic apparatus, the pellicle assembly including the pellicle membrane according to claim 1.

23. (canceled)

24. A lithographic apparatus comprising the pellicle membrane according to claim 1.
